(19) United States
(12) Patent Application Publication
(10) Pub. No.: US 2011/0142384 A1
(43) Pub. Date: Jun. 16, 2011

(54) SLIDING ELEMENT HAVING A MULTIPLE LAYER

(76) Inventor: Dieter Hofmann, Gelnhausen (DE)

(21) Appl. No.: 13/058,219

(22) PCT Filed: Aug. 13, 2009
(86) PCT No.: PCT/EP2009/005879

§ 371 Date: Feb. 9, 2011

(30) Foreign Application Priority Data
Aug. 15, 2008 (DE) 10 2008 037 871.2

(51) Int. Cl. F16C 33/02; B32B 7/02; B32B 5/00; B32B 3/30; B32B 15/04; B32B 9/04; B05D 1/36; C23C 16/44; F16C 29/02

(52) U.S. Cl. 384/42; 428/217; 428/336; 428/172; 428/332; 428/457; 428/446; 428/497; 427/402; 427/248.1; 427/255.28; 508/100; 508/109; 508/107

(57) ABSTRACT

The invention relates to a sliding element that includes a carrier body and a multiple layer. The multiple layer includes a running layer and a protective layer, in which the protective layer has a hardness HUₚₗₐₛₜ of greater than 5 GPa, and the hardness of the running layer is less than 400 HV.

The present invention relates to a sliding element having a multiple layer, which is suitable for mechanical bearings, in particular for sliding-contact bearings which are subjected to high levels of loading, as are used in mechanical and automotive engineering.

Mechanical bearings consist of sliding partners which move in relation to one another and are also referred to as a sliding element and counterpart. The sliding element generally serves as a guide for the counterpart. By way of example, in the case of a sliding-contact bearing the counterpart is designed as a cylindrical shaft and the sliding element is designed as a bushing or bearing shell which matches the latter. The inner side of the bearing shell, which makes contact with the outer surface of the shaft, acts as a running surface for the shaft. The shape of the bearing shell usually differs slightly from the cylindrical shape of the shaft, and therefore a gap with a width in the order of magnitude of micrometers remains between the shaft and the bearing shell. A lubricant, for example oil, is located in this gap.

In mechanical bearings in general, and particularly in sliding-contact bearings for internal combustion engines, particular importance is attached to what is known as the running-in operation. In the first hours for which the engine is running, the sliding partners are matched and, associated with this, the surface irregularities are smoothed at the individual sliding points. This operation is associated with a certain degree of wear. In modern automobile engines, the running-in operation is concluded after about 20 to 30 hours of operation, but in individual cases even only after more than 100 hours of operation.

The friction behavior of a bearing is described by the Stribeck curve, which plots the coefficient of friction μ as a function of the sliding speed v or rotational speed n (in the case of sliding-contact bearings). A distinction is made between three regions in the Stribeck curve:
solid or static friction at a low sliding speed or rotational speed,
mixed friction at an average sliding speed or rotational speed, and
liquid friction at a high sliding speed or rotational speed.

In the region of solid friction, the coefficient of friction and, associated with this, the wear increase greatly as the sliding speed decreases. In the region of liquid friction, the coefficient of friction increases as the sliding speed increases. At the transition from solid friction to liquid friction, in the region of so-called mixed friction, the coefficient of friction passes through a minimum; this point on the Stribeck curve is also referred to as the release point.

During operation of an engine, all three regions of the friction behavior are run through. It is therefore necessary to equip the running surface of sliding-contact bearings with a wear-resistant and fatigue-resistant coating. This applies particularly to the bearings of crankshafts in high-compression diesel and gasoline engines. A layer which is produced by means of PVD or sputtering, consists of a mixture of the metals aluminum (Al), tin (Sn) and, if appropriate, copper (Cu) and has a thickness in the range of 5 to 30 μm has proved to be suitable, in particular, for this purpose (see e.g. DE 36 29 451 C2). By means of special sputtering processes and heat-conditioning processes carried out simultaneously or thereafter, a special metallurgical microstructure having a micro hardness in the range of about 80 to 200 HV and good sliding properties is produced in the aluminum/tin layer. The good sliding properties of aluminum/tin layers result from the sponge-like microstructure of the Al; this promotes the escape of Sn, which acts as a “metallic lubricant film” on the running surface. In addition to its lubricating action, the aluminum/tin layer has good properties for taking up microscopically small abrasion particles, which are produced in mechanical bearings primarily during the running-in phase and, on a smaller scale, during continued operation (so-called residual waste and oil residues). Abrasion particles having a hardness which exceeds a specific value are pressed into or embedded in the aluminum/tin layer. The aluminum/tin layer therefore satisfies opposing demands:
a hardness in the range of 80 to 200 HV (Vickers hardness) and an associated stability,
good sliding properties (Sn lubrication),
the ability to take up (embedding) hard abrasion particles.

Owing to the advantageous combination of these properties, aluminum-tin alloys are increasingly being used in running layers for mechanical bearings.

WO 2007/079834 describes a sliding element comprising a first or inner wear layer and an outer run-in layer, which is made of carbon and contains hydrogen and nanocrystalline carbide phases. The run-in layer consists of metal-containing, amorphous, hard carbon of the Me—C:H type, tungsten being preferred as the metal. In particular, the run-in layer is a layer which is produced by means of PVD and consists of diamond-like carbon (DLC). The thickness of the run-in layer is 1 to 5 μm. The wear layer is formed as a nitrided layer, as an electroplated layer, as a thermally sprayed layer and/or as a hard material layer deposited by means of thin film technology.

U.S. Pat. No. 6,095,690 discloses a sliding-contact bearing comprising a metallic base body and a metallic base layer which is applied to the base body and comprises a multiplicity of depressions for the reception of oil. The depressions or oil pockets have a depth of 0.03 to 3 mm and the width thereof is 10 to 40 times the depth. The base layer is preferably produced by electroplating or by means of sputtering and consists of alloys such as AlNi2MnCu, AlZn5SiCuPbMg, AlSn6, CuPb22Sn, CuPb17Sn5, CuPb10Sn10, CuPb22S3, PbSn10Cu2, PbSn10Cu5 or PbSn14Cu8, preferably of AlSn20.

U.S. Pat. No. 5,238,311 discloses a sliding-contact bearing for internal combustion engines which has increased resistance to abrasion. The bearing shell of the sliding-contact bearing is equipped with cylindrically or circularly or helically circulating grooves having a width of less than 0.6 mm and a depth of less than 15 μm. In addition, the bearing shell is provided with a first and a second layer which are each deposited by electroplating and consist of an aluminum-lead alloy or nickel. The pressure resistance or micro hardness of the top nickel layer is up to 60 MPa. The two electroplated layers are deposited on a base layer which is provided with grooves and has been applied to a bearing body made of steel.

The base layer consists of kelmet (lead-copper alloy) or an aluminum alloy such as AlSnCu.

U.S. Pat. No. 5,620,262 describes a sliding-contact bearing comprising a bearing body with a base layer and a first and a second coating deposited on the base layer. The base layer is provided with cylindrically or circularly circulating grooves. The first and second coatings have a thickness in the region of less than 2 μm or in the range of 1 to 8 μm. The height of the webs between adjacent grooves amounts to 70 to 200% of the thickness of the second coating, i.e. 0.7 to 16 μm. The materials used are as follows: an aluminum or copper alloy such as Cu-23/Pb-3/Sn or Cu-1/Ag for the base layer; metals deposited by electroplating, such as Ni, Cu, Cr or Fe, for the first coating; and a lead-containing alloy, such as Pb-10/Sn-2/Cu, pure tin or a tin alloy for the second coating.

U.S. Pat. No. 6,059,460 discloses a sliding element for sliding-contact bearings. The running surface of the sliding element comprises a system of cylindrically or circularly circulating grooves and webs having a depth and width or height and width in the region of a few micrometers. The grooves serve to receive a lubricant, such as oil, whereas the webs minimize the contact surface between the sliding element and the counterpart (shaft). The cross-sectional profile of the grooves and webs may be configured like a triangle, rectangle, trapezoid or wave.

U.S. Pat. No. 6,739,238 discloses bearings for internal combustion engines comprising sliding elements, which move in relation to one another, and a film of lubricating oil, which is located between the sliding elements and in which laminar flow conditions prevail. The opposing surfaces of the sliding elements comprise irregular microscopic elevations and a multiplicity of dimples, wherein the mean maximum depth of the dimples is greater than the maximum height of the elevations and the mean maximum diameter of the dimples of one sliding element is smaller than the mean minimum distance between the dimples of the opposite sliding element. In another configuration, the surfaces of the sliding elements comprise grooves, the dimensions of which are in specific relationships with respect to one another and with respect to the gap between opposing sliding elements.

The bearings known in the prior art have one or more of the following disadvantages:
failure of the running layer exposes lower-lying materials which produce a critical material pairing with the counterpart of the bearing with respect to friction, with increased wear or unfavorable consumption and an associated high failure rate;
failure of the running layer exposes lower-lying materials which are harmful to the environment if they are abraded, for example lead-containing materials which pass into the environment inter alia via the lubricant; and
in the case of bearings subjected to high levels of loading, it is not possible to use running layers with structured surfaces, for example dimples, because the hardness of the running layer is not high enough to withstand high specific or point surface loading.

It is an object of the present invention to avoid the disadvantages mentioned above and to provide sliding elements for bearings having an increased wear resistance and fatigue strength. Within the context of this object, the intention is also to provide a process for producing the sliding elements according to the invention and also bearings having an increased wear resistance and fatigue strength which contain these sliding elements.

This object is achieved by a sliding element made of a carrier body having a multiple layer, comprising an outer running layer and an inner protective layer having a hardness HUₚₗₐₛₜ of greater than 5 GPa, preferably greater than 10 GPa, in particular greater than 20 GPa and particularly preferably greater than 40 GPa.

The plastic hardness HUₚₗₐₛₜ is preferably measured in accordance with DIN EN ISO 14577, e.g. using a diamond test head having a radius of 200 μm.

Materials which contain diamond-like carbon (DLC), for example DLC, Me-DLC, W-DLC, Ti-DLC, Cr-DLC, are suitable as the material for the protective layer. Ceramic materials such as silicon nitride can also be used for the protective layer. The protective layer is preferably deposited by means of PVD and/or PCVD.

Compared to the protective layer, the running layer has a low hardness of only 10 to 400 HV, but is distinguished by good sliding properties. The hardness HV of the running layer is measured, for example, in accordance with DIN EN ISO 6507. 400 HV corresponds to about 0.4 GPa. The hardness of the running layer is high enough to effectively withstand the loading which occurs under normal operating conditions. In the event of a peak load, which rarely occurs, the running layer may be damaged locally, in which case the underlying hard protective layer is exposed and comes into contact with the counterpart of the bearing. Abrasion particles which may possibly be present cannot penetrate into the protective layer owing to the high hardness of the latter and are embedded in the running layer which remains.

The running layer preferably has a hardness of 60 to 200 HV and in particular of 80 to 140 HV. In particular, the protective layer contains diamond-like carbon (DLC), preferably DLC having a hardness of greater than 30 GPa. In a further configuration of the invention, the protective layer contains a material selected from the group consisting of DLC, Me-DLC, W-DLC, Ti-DLC, Cr-DLC and silicon nitride or mixtures thereof. The protective layer is preferably produced by means of PVD and/or PCVD and has a thickness of 0.2 to 10 μm, preferably 0.5 to 8 μm and in particular 1 to 5 μm. In one development of the invention, the sliding element comprises one or more structured inner surfaces comprising a multiplicity of depressions and/or elevations. In this case, the maximum difference in height measured perpendicularly to the respective surface (peak-to-valley value, e.g. in accordance with DIN 4768 Part 1) is less than 200 μm, preferably 100 μm and in particular 20 μm. Before the application of the protective layer and, if appropriate, further layers, the structural parameters of the inner surfaces can be determined by means of known measurement processes, e.g. in accordance with DIN 4768 Part 1, DIN EN ISO 4287, DIN EN 10049 or DIN EN ISO 13565. The measurement instruments used in this case are preferably Profilometer or Atomic Force Microscope, for example Taylor Hobson Talysurf 6 or Digital Instruments Dimension 3100. As an alternative to this, it is possible to analyze and measure sections of sliding elements having a complete multiple layer by means of optical or electron microscopy.

In a further configuration of the invention, the inner surfaces comprise a multiplicity of depressions having a maximum lateral dimension of 0.5 to 1500 μm, preferably 5 to 100 μm and in particular 10 to 20 μm; and a maximum depth of 0.5 to 200 μm, preferably 1 to 200 μm and in particular 1 to μm. In another advantageous development, the inner surfaces comprise a multiplicity of grooves having a maximum width of 0.5 to 2000 μm, preferably 5 to 200 μm and in particular 10 to 20 μm; and a maximum depth of 0.5 to 200 μm, preferably 1 to 100 μm and in particular 1 to 20 μm. In particular, the surface of the carrier body may be structured and equipped with a multiplicity of depressions and/or elevations. In order to increase the bond strength, a bonding layer which preferably contains Ti, TiNₓ, Cr, CrN_{y}, Ni, NiCr or a Cr/NiCr alloy and has a thickness of 0.2 to 5 μm, preferably 0.5 to 3 μm, is arranged between the protective layer and the carrier body.

Further advantageous configurations of the invention are distinguished by the fact that:
the multiple layer comprises a base layer arranged between the protective layer and the carrier body, wherein the base layer preferably consists of bronze, brass or an aluminum alloy and has a thickness of 100 to 2000 μm, preferably 100 to 800 μm and in particular 200 to 500 μm;
the surface of the base layer is configured as a structured surface comprising depressions and/or elevations;
the multiple layer comprises a bonding layer arranged between the protective layer and the base layer, wherein the bonding layer preferably contains Ti, TiNₓ, Cr, CrN_{y}, Ni, NiCr or a Cr/NiCr alloy and has a thickness of 0.2 to 5 μm, preferably 0.5 to 3 μm;
the carrier body consists of metal, preferably of steel;
the carrier body consists of silicon nitride;
the multiple layer comprises an intermediate layer arranged between the protective layer and the running layer, wherein the intermediate layer preferably contains Cr, Ni, NiCr or a Cr/NiCr alloy and has a thickness of 0.2 to 5 μm, preferably 0.5 to 3 μm;
the running layer contains a metal or an alloy of a plurality of metals and/or silicon carbide (SiC);
the running layer contains AlSn, AlSn20, AlSn20Cu or AlSn25Cu;
the running layer has been produced by means of cathode sputtering or vapor deposition processes;
the running layer contains PbSn18Cu2, PbSn10TiO₂, CuPb30 or CuPb40;
the running layer has been produced by means of electrolytic processes;
the running layer contains AgSn85CuNi;
the running layer is coated with lubricating varnish; and
the running layer consists of lubricating varnish.

Furthermore, the invention relates to embodiments which are characterized in that:
the multiple layer comprises an intermediate layer arranged between the protective layer and the running layer, wherein the intermediate layer contains a metal (Me), preferably a carbide-forming metal selected from the group consisting of Ti, V, Cr, Zr, Nb, Mo, Hf, Ta, W, Re and Si; the intermediate layer contains a first partial intermediate layer adjacent to the protective layer and a second partial intermediate layer adjacent to the running layer and also a third partial intermediate layer arranged between the first and second partial intermediate layers; the first partial intermediate layer comprises a transition layer, which is optionally graduated with the protective layer, and subsequently a non-graduated layer which consists of Me-DLC or of Si-DLC; the second partial intermediate layer consists of Me and is optionally designed so as to be graduated with the first partial intermediate layer; the optional third partial intermediate layer consists of metal carbide (MeCₓ) or SICₓ and is optionally designed so as to be graduated with the first and/or second partial intermediate layer; and the intermediate layer has an overall thickness of 0.2 to 5 μm, preferably 0.3 to 0.6 μm;
the multiple layer comprises a bonding layer arranged between the protective layer and the carrier body or between the protective layer and the base layer, wherein the bonding layer comprises a first partial bonding layer adjacent to the carrier body or to the base layer and a second partial bonding layer which is adjacent to the protective layer and is optionally designed so as to be graduated with the first partial intermediate layer; the first partial bonding layer consists of Ti or Cr and the second partial bonding layer consists of titanium nitride (TiNₓ) or chromium nitride (CrNₓ); and the bonding layer has an overall thickness of 0.2 to 5 μm, preferably 0.3 to 0.6 μm; and
the protective layer comprises a first partial protective layer adjacent to the bonding layer, to the base layer or to the carrier body and a second partial protective layer which is adjacent to the first partial protective layer and is optionally designed so as to be graduated with the first partial protective layer and also possibly a third partial protective layer which is arranged between the second partial protective layer and the running layer or the intermediate layer and is optionally designed so as to be graduated with the second partial protective layer; the first partial protective layer consists of a metal carbide MeCₓ with Me selected from the group consisting of Ti, V, Cr, Zr, Nb, Mo, Hf, Ta, W and Re, in particular consists of titanium carbide (TiCₓ) or tungsten carbide (WCₓ) or SiCₓ; the second partial protective layer consists of Me-DLC or Si-DLC, in particular of Ti-DLC or W-DLC; the optional third partial protective layer consists of DLC; and the protective layer has an overall thickness of 0.5 to 10 μm, in particular 1 to 4 μm.

The above-mentioned “graduated transition layer” consisting of the protective layer material (Me-DLC, Si-DLC or DLC), the carbide-forming metal (Me) or Si is preferably produced by means of PVD and/or PECVD, in that the amount of a carbon-containing gas, for example acetylene, fed to the coating chamber is continuously reduced in a known manner, such that the quantitative fraction of carbon in the layer is reduced as the thickness of the deposited layer increases.

The sliding element according to the invention is suitable for use in cylinders, pistons and piston rings of internal combustion engines and can advantageously be used as a constituent part of a sliding-contact bearing, for example as a split shell for sliding-contact bearings. Planar or cylindrical embodiments of the sliding element according to the invention are suitable for use in linear guides.

It is possible to use one or more sliding elements according to the invention in various types of mechanical bearings, for example in hydrodynamic and hydrostatic bearings, in air bearings, in rolling bearings, in particular in ball bearings and also in magnetic bearings.

A process for producing sliding elements according to the invention, which are described above, comprises the following steps:
a) a surface of a carrier body, which is possibly equipped with a base layer or bonding layer, is optionally structured;
b) a protective layer having a hardness HUₚₗₐₛₜ of greater than 5 GPa is applied to the surface of the carrier body, wherein the protective layer is preferably deposited by means of PVD and/or PCVD;
c) an intermediate layer is optionally applied to the protective layer;
d) a running layer is applied to the protective layer or optionally to the intermediate layer; and
e) lubricating varnish is optionally applied to the running layer.

The invention achieves the advantage that the sliding element still has very good running properties even when the running layer is partially destroyed and the counterpart of the bearing is in contact with the exposed, preferably structured protective layer. Abrasion particles are then embedded in the depressions in the protective layer, in which there is material of the running layer. The hardness of the material of the running layer is less than that of the material of the protective layer. The very hard protective layer is unable to take up any abrasion particles and remains undamaged. In addition, the protective layer has good sliding properties. Since the abrasion particles are deposited in the depressions in the protective layer, the degree of wear on the counterpart of the bearing is minimized.

In the text which follows, the invention is explained in more detail on the basis of figures. Schematically:

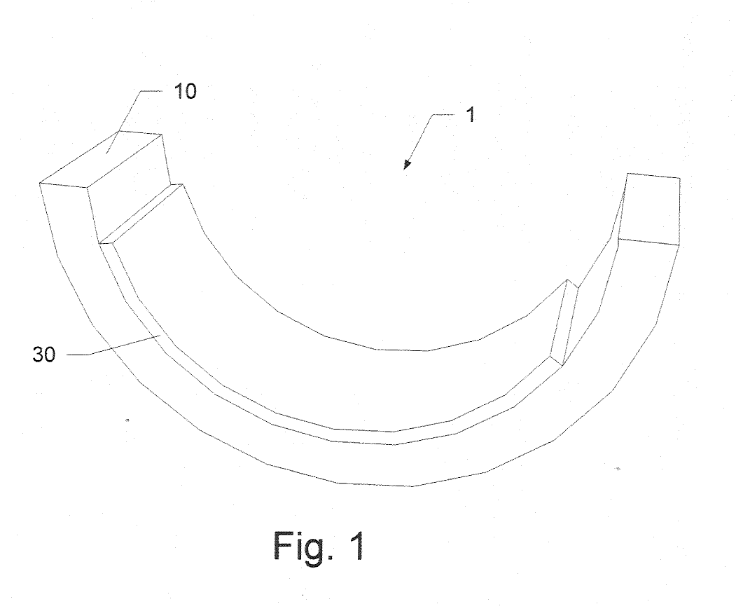

FIG. 1 shows a perspective sectional view of a bearing shell for a sliding-contact bearing;

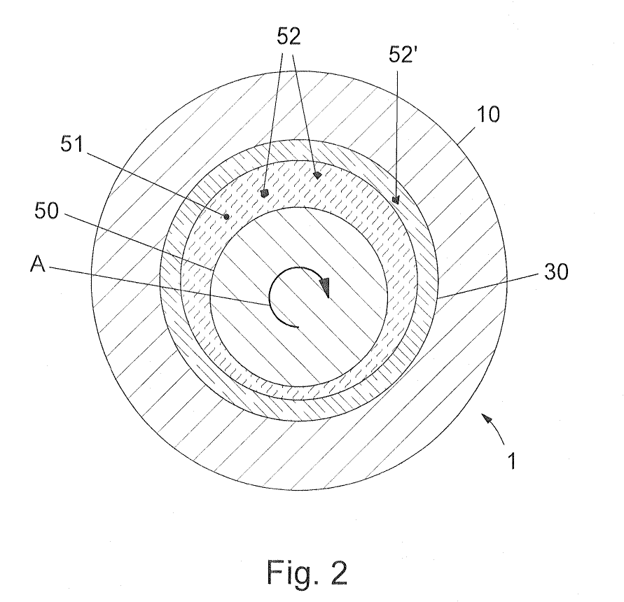

FIG. 2 shows a cross section through a sliding-contact bearing with a bearing shell and a shaft;

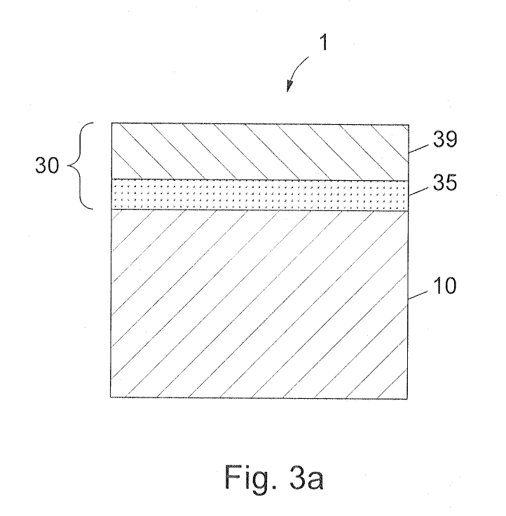

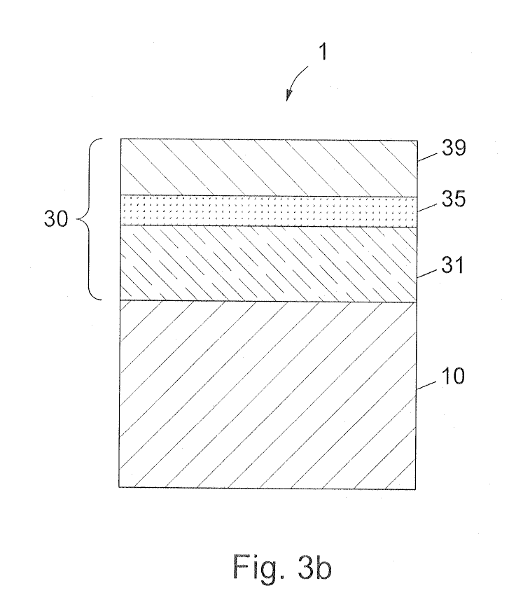

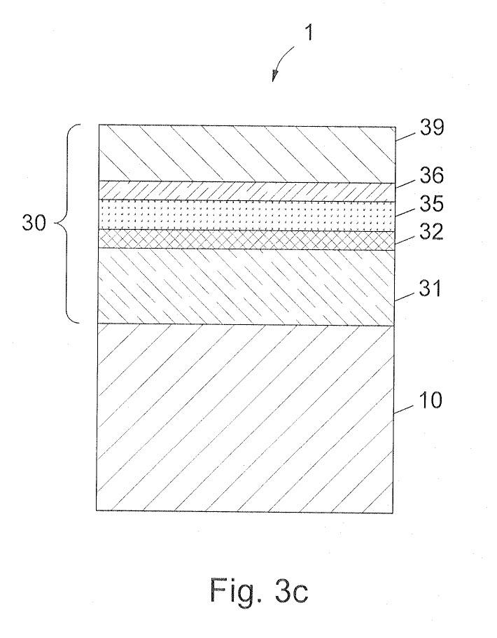

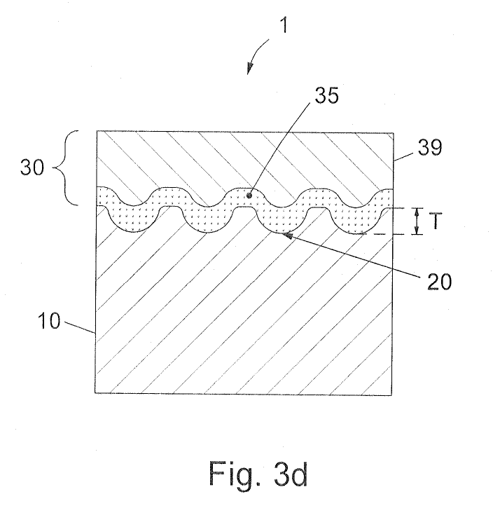

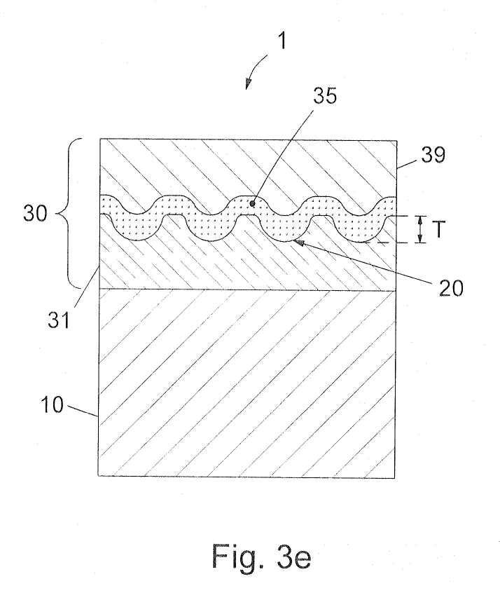

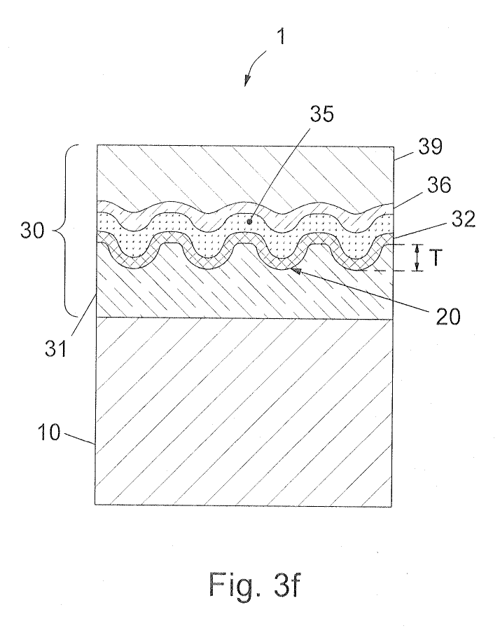

FIGS. 3a-f show various embodiments of the sliding elements having a protective layer; and

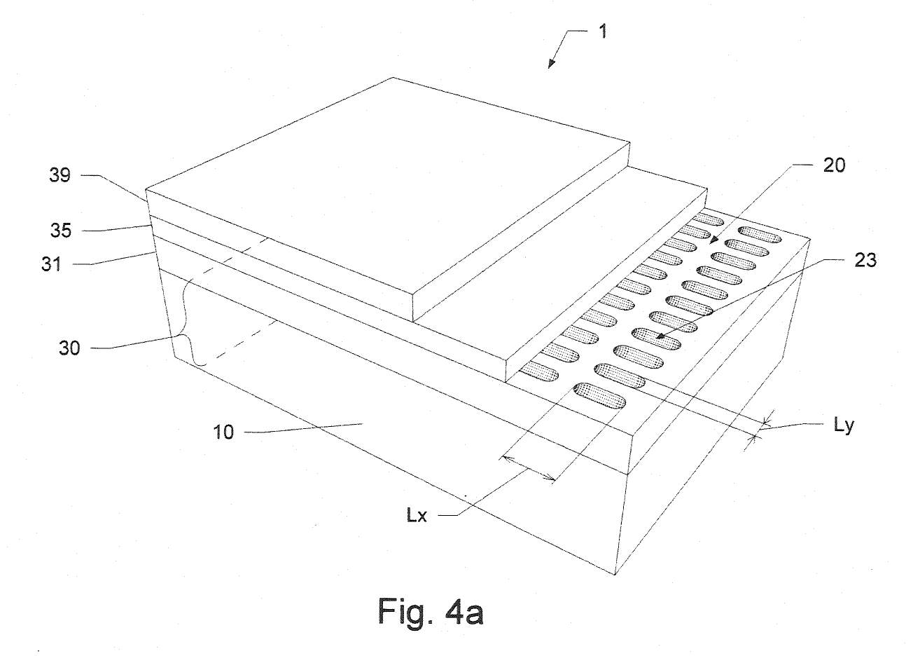

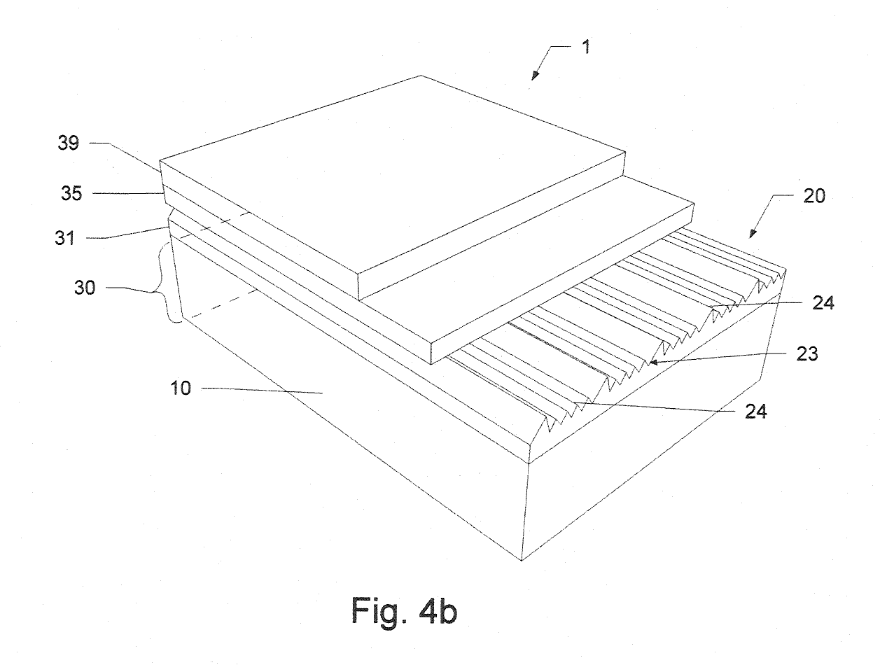

FIGS. 4a-b show perspective views of sliding elements according to the invention having a surface structured on the inside.

FIG. 1 shows a sliding element 1 comprising a carrier body 10, on which a multiple layer 30 is applied. The basic structure of the carrier body 10 and multiple layer 30 is known in the prior art. The carrier body 10 shown in FIG. 1 has a semicylindrical shape, as is suitable for sliding-contact bearings. According to the invention, it is also possible for the carrier body 10 to have any other desired shape. By way of example, a carrier body 10 having a planar surface is suitable for linear guides. An annularly configured carrier body 10 is provided for piston rings.

FIG. 2 shows a sliding-contact bearing comprising a cylindrical sliding element 1, a counterpart 50 and a lubricating film 51. The sliding element 1 comprises the carrier body 10 and the multiple layer 30. A lubricating film 51, which generally consists of natural or synthetic oil, is located between the sliding element 1 and the counterpart 50. The relative movement between the sliding element 1 and the counterpart 50 is indicated by an arrow A. It may be the case that abrasion particles 52 are present in the lubricating film 51. If an abrasion particle 52′ has a sufficiently high hardness, it may be pressed into or embedded in the multiple layer 30 by the counterpart 50.

FIG. 3a shows a cross section of a first embodiment of the sliding element 1 according to the invention, in which the multiple layer 30 comprises a running layer 39 and a protective layer 35. The protective layer 35 is located on the carrier body 10.

FIG. 3b shows a further embodiment according to the invention, in which, in addition to the running layer 39 and the protective layer 35, the multiple layer 30 comprises a base layer 31 arranged between the carrier body 10 and the protective layer 35.

FIG. 3c shows another embodiment of a sliding element 1 according to the invention, in which the multiple layer 30 comprises a bonding layer 32 and an intermediate layer 36. The bonding layer 32 and the intermediate layer 36 are arranged between the protective layer 35 and the base layer 31 and, respectively, between the protective layer 35 and the running layer 39.

In advantageous developments of the invention, one or more inner surfaces of the sliding element 1 are structured. The inner surface(s) is (are) preferably the surface of the carrier body 10 or the surface of the base layer 31.

FIG. 3d shows a sliding element 1 in section, the carrier body 10 of which has a structured surface 20. By way of example, the surface 20 comprises stamped formations with a depth T. The protective layer 35, which has a course comparable to that of the surface 20, is located on the surface 20. The running layer 39 is located on the protective layer 35.

FIG. 3e shows an embodiment of the sliding element 1, in which the surface 20 of the base layer 31 is structured. Reference symbols 30, 35, 39 and T have the same meaning as in FIG. 3d.

FIG. 3f shows a sliding element 1 having a similar structure to the sliding element shown in FIG. 3c, the surface 20 of the base layer 31 being structured. The bonding layer 32, which fixes the protective layer 35 to the base layer 31, is located on the surface 20. The intermediate layer 36 applied to the protective layer 35 serves to join the protective layer 35 to the running layer 39.

In FIGS. 3d-f and 4a-b, the surface of the running layer 39 is planar. This is only achieved when the thickness of the protective layer 35 and/or of the running layer 39 and also, if appropriate, of further layers, which cover the structured surface(s) 20, is sufficiently large to level out or to planarize the depressions/elevations in the surface(s) 20. This is generally not the case; instead, the protective layer and, if appropriate, the running layer 39 have a course which conforms to the structured surface(s) 20. Accordingly, the invention also encompasses those sliding elements 1 in which the protective layer 35 and, if appropriate, the running layer 39 are designed so as to substantially conform to the structured surface(s) 20.

A sliding element 1 according to the invention, in which the protective layer 35 has a course which conforms to the structured surface(s) 20 with a multiplicity of depressions, is distinguished by a particularly advantageous protective action based on the following effects:
i) If the running layer 39 is destroyed over a large area, residual material of the running layer 39 remains in the depressions in the protective layer 35. This residual material is available for the embedding of abrasion particles, which cannot penetrate into the protective layer 35 owing to the high hardness thereof.
ii) Owing to the numerous depressions in the protective layer 35, the contact surface with the counterpart of the bearing is reduced and, associated with this, the resistance to friction on the counterpart is reduced.

FIG. 4a shows a perspective view of a sliding element 1 having a structured surface 20 comprising a multiplicity of regularly arranged depressions or dimples 23 in the base layer 31. For the rest, the structure of this sliding element 1 corresponds to the structure of the sliding element shown in FIG. 3b. The depressions 23, with lateral dimensions or length Lx and width Ly, can be produced by means of known methods, such as embossing or chemical etching. A regular arrangement is not necessary; both the shape and the relative arrangement of the depressions 23 may be irregular.

FIG. 4b shows a further embodiment of the invention, in which the surface 20 of the base layer 31 is structured with grooves or furrows and comprises depressions 23 and elevations 24. The grooves may be dimensioned and arranged irregularly.

The inner surface(s) 20 is/are structured by means of various known methods. By way of example, in this case use is made of mechanical methods, such as embossing, milling, turning, grinding, shot blasting and the like, high-energy radiation, e.g. laser or electron radiation, or chemical etching processes, if appropriate in combination with photolithographically structured etching masks.

Materials suitable for the base layer 31 are, in particular, alloys based on tin, bismuth, indium, lead or aluminum and also alloys based on CuPb, which may possibly have a high lead content, or based on Al Sn or on AlBi. Tin-based alloys with a high tin content are particularly advantageous. It is also possible to use lead-free copper-based alloys. Examples of copper-based materials are CuPb22Sn2, CuPb10Sn10, CuPb15-Sn7, CuSn6, CuSn4Zn. With respect to the relatively low environmental pollution, lead-free copper alloys based on CuAl, CuSn, CuZn, CuZnSn and CuBi are particularly advantageous. Examples of tin-based materials are Sn8Cu4, SnSb2, Cu6Pb. Examples of lead-based materials are PbSb10Sn6, PbSb15Sn10, PbSb15-SnAs. Examples of possible aluminum-based materials are AlSn40, AlSn20, AlSn25, AlSn10, AlSn6, etc.

It is also possible to use a material based on AlZn, e.g. AlZn4SiPb, or based on AlSi, e.g. AlSiCuMgNi, or based on AlSnSi, e.g. AlSn20Si4, for the base layer 31. By way of example, the base layer 31 may be applied to the carrier body by electroplating, by cladding, roll cladding, etc., as is known from the prior art.

The running layer 35 is preferably deposited with the aid of a sputtering process, vapor deposition or electroplating. In this case, it is possible to deposit the alloys or metals known from the prior art, for example aluminum alloys, aluminum-based alloys containing lead and/or bismuth and/or indium and/or tin as alloying elements, copper-based alloys, silver-based alloys containing lead and/or bismuth and/or indium and/or tin, a silver-lead alloy or the like. The list of alloys which can possibly be used is non-exhaustive and it goes without saying that it is also possible to process alloys or mixtures other than those mentioned, where in turn particular preference is given to the use of lead-free alloys. Since sputtering processes are known per se, reference is made at this point to the relevant literature. The alloys for sputtering may contain aluminum in the range between 50% by weight and 90% by weight, for example in the range between 55% by weight and 80% by weight, preferably in the range between 60% by weight and 79% by weight, in particular in the range between 64% by weight and 70% by weight, and also tin in the range between 5% by weight and 45% by weight, for example in the range between 10% by weight and 39% by weight, preferably in the range between 12% by weight and 32% by weight, in particular in the range between 17% by weight and 20% by weight.

Other alloying elements, e.g. manganese, iron, cobalt or the like, may be present for the formation of specific alloy phases, e.g. hard materials. By way of example, further alloying elements would be Ag, Al, Fe, Cu, Ni, Sc, Si, Zn, Mn, Co, Cr, Zr, Mg.

If a lubricating varnish is used for the running layer 39, this contains at least one thermoplastic resin as the main constituent, this thermoplastic resin being selected, in particular, from a group consisting of polyimides, polyamidimides, in particular aromatic polyamidimides, polyaryletherimides, in particular aromatic polyaryletherimides, if appropriate modified with isocyanates, phenolic resins, polyaryl ether ether ketones, polyamides, epoxy resins, in particular aromatic epoxy resins, polytetrafluoroethylene, fluorine-containing resins, e.g. polyfluoroalkoxy-polytetrafluoroethylene copolymers, ethylene tetrafluoroethylene, fluorinated ethylene-propylene copolymers, polyvinylidene difluoride, polyvinyl fluoride, allylene sulfide, polytriazo-pyromellitimides, polyesterimides, polyaryl sulfides, polyvinylene sulfides, polysulfones, polyaryl sulfones, polyaryl oxides, copolymers and mixtures thereof, e.g. polyimides and/or polyamidimides and/or polyaryletherimides and/or phenolic resins and/or polyaryl ether ether ketones and/or polyamides and/or epoxy resins and/or polytetrafluoroethylene and/or fluorine-containing resins, e.g. polyfluoroalkoxy-polytetrafluoroethylene copolymers, ethylene tetrafluoroethylene, fluorinated ethylene-propylene copolymers, polyvinylidene difluoride, polyvinyl fluoride, allylene sulfide and/or polytriazo-pyromellitimide and/or polyesterimide and/or polyvinylene sulfide and/or polysulfones and/or polyaryl sulfones and/or polyaryl oxides with polyimides and/or polyamidimides and/or polyaryletherimides and/or phenolic resins and/or polyaryl ether ether ketones and/or polyamides and/or epoxy resins and/or polytetrafluoroethylene and/or fluorine-containing resins, e.g. polyfluoroalkoxy-polytetrafluoroethylene copolymers, ethylene tetrafluoroethylene, fluorinated ethylene-propylene copolymers, polyvinylidene difluorides, polyvinyl fluorides and/or allylene sulfides and/or polytriazo-pyromellitimides and/or polyesterimides and/or polyaryl sulfides and/or polyvinylene sulfides and/or polyaryl sulfones and/or polyaryl oxides. It is advantageous here that a cyclic temperature-dependent softening and hardening mechanism is made possible by the lubricating varnish which consists primarily of the thermoplastic resin or resin mixtures or copolymers, as a result of which the service life of the layer of lubricating varnish can be increased. It is also advantageous that the bearing function can be adapted to different instances of loading owing to the specifically mentioned resins or resin mixtures or copolymers, and therefore expensive types of resin can be used only for bearing elements which can be subjected to high levels of loading and, as a result, it is possible to achieve a benefit in terms of cost for bearing elements subjected to lower levels of loading.

The resin content of the lubricating varnish can be selected from a range with a lower limit of 30% and an upper limit of 95%. It is thereby possible to vary the transferability of the deformation to the substrate, and therefore the running properties of the layer of lubricating varnish, in particular in the running-in phase, can be adapted better to the respective requirements.

To further improve this effect, it is possible to select the resin content of the lubricating varnish from a range with a lower limit of 50% by weight and an upper limit of 85% by weight or from a range with a lower limit of 70% by weight and an upper limit of 75% by weight.

The thermoplastic resin may contain at least one additive selected from a group consisting of lubricants, in particular MoS₂, h-BN, WS₂, graphite, polytetrafluoroethylene, Pb, Pb—Sn alloys, CF₂, PbF₂, also hard materials, e.g. CrO₃, Fe₃O₄, PbO, ZnO, CdO, Al₂O₃, SiC, Si₃N₄, SiO₂, Si₃N₄, also clay, talc, TiO₂, mullite, CaC₂, Zn, AlN, Fe₃P, Fe₂B, Ni₂B, FeB, metal sulfides, e.g. ZnS, Ag₂S, CuS, FeS, FeS₂, Sb₂S₃, PbS, Bi₂S₃, CdS, fibers, in particular inorganic fibers, e.g. glass, carbon, potassium titanate, whiskers, for example SiC, metal fibers, for example of Cu or steel, and also mixtures thereof, e.g. at least one lubricant, in particular of the type mentioned, and/or at least one hard material, in particular of the type mentioned, and/or at least one metal sulfide, in particular of the type mentioned, and/or at least one fibrous additive, in particular of the type mentioned, with at least one lubricant and/or one hard material and/or one metal sulfide and/or at least one fibrous additive, all in particular of the type mentioned.

1. A sliding element comprising a carrier body having a multiple layer, said multiple layer comprising an outer running layer and an inner protective layer having a hardness HUₚₗₐₛₜ of greater than 5 GPa.

2. The sliding element as claimed in claim 1, wherein the protective layer has a hardness HUₚₗₐₛₜ of greater than 10 GPa.

3. The sliding element as claimed in claim 1, wherein the running layer has a hardness of 10 to 400 HV.

4. The sliding element as claimed in claim 1, wherein the protective layer contains diamond-like carbon (DLC).

5. The sliding element as claimed in claim 1, wherein the protective layer contains a material selected from the group consisting of DLC, Me-DLC, W-DLC, Ti-DLC, Cr-DLC and silicon nitride or mixtures thereof.

6. The sliding element as claimed in claim 1, wherein the protective layer is produced by means of PVD and/or PCVD and has a thickness of 0.2 to 10 μm.

7. The sliding element as claimed in claim 1, wherein said sliding element comprises at least one structured inner surface comprising a multiplicity of depressions and/or elevations.

8. The sliding element as claimed in claim 7, wherein the maximum difference in height measured perpendicularly to the surface(s) (peak-to-valley value in accordance with DIN 4768 Part 1) is less than 200 μm.

9. The sliding element as claimed in claim 7, wherein the inner surface(s) comprise a multiplicity of depressions having a maximum lateral dimension of 0.5 to 1500 μm; and a maximum depth of 0.5 to 200 μm.

10. The sliding element as claimed in claim 7, wherein the inner surface(s) comprise a multiplicity of grooves having
a maximum width of 0.5 to 2000 μm; and
a maximum depth of 0.5 to 200 μm.

11. The sliding element as claimed in claim 7, wherein the carrier body has a structured surface comprising depressions and/or elevations.

12. The sliding element as claimed in claim 1, wherein the multiple layer comprises a bonding layer arranged between the protective layer and the carrier body, wherein the bonding layer has a thickness of 0.2 to 5 5 μm.

13. The sliding element as claimed in claim 1, wherein the multiple layer comprises a base layer arranged between the protective layer and the carrier body, and the base layer has a thickness of 100 to 2000 μm.

14. The sliding element as claimed in claim 13, wherein the base layer has a structured surface comprising depressions and/or elevations.

15. The sliding element as claimed in claim 13, wherein the multiple layer comprises a bonding layer arranged between the protective layer and the base layer, and the bonding layer has a thickness of 0.2 to 5 μm.

16. The sliding element as claimed in claim 1, wherein the carrier body consists of metal.

17. The sliding element as claimed in claim 1, wherein the carrier body consists of silicon nitride.

18. The sliding element as claimed in claim 1, wherein the multiple layer comprises an intermediate layer arranged between the protective layer and the running layer, and the intermediate layer has a thickness of 0.2 to 5 μm.

19. The sliding element as claimed in claim 1, wherein the running layer contains a metal, an alloy of a plurality of metals and/or SiC.

20. The sliding element as claimed in claim 19, wherein the running layer contains AlSn, AlSn20, AlSn20Cu, AlSn25Cu.

21. The sliding element as claimed in claim 19, wherein the running layer has been produced by means of cathode sputtering or vapor deposition processes.

22. The sliding element as claimed in claim 19, wherein the running layer contains PbSn18Cu2, PbSn10TiO₂, CuPb30 or CuPb40.

23. The sliding element as claimed in claim 19, wherein the running layer has been produced by electrolytic processes.

24. The sliding element as claimed in claim 19, wherein the running layer contains AgSn85CuNi.

25. The sliding element as claimed in claim 1, wherein the running layer is coated with lubricating varnish.

26. The sliding element as claimed in claim 1, wherein the running layer consists of lubricating varnish.

27. The sliding element as claimed in claim 1, wherein said sliding element is configured as a split shell for sliding-contact bearings.

28. Cylinders, pistons and piston rings of internal combustion engines comprising a sliding element as claimed in claim 1.

29. Linear guides comprising a sliding element as claimed in claim 1.

30. A mechanical bearing comprising one or more sliding elements as claimed in claim 1.

31. A process for producing a sliding element as claimed in claim 1, said process comprising the following steps:
a) providing a surface of a carrier body, said carrier body optionally including a base layer and is optionally structured;
b) applying a protective layer having a hardness HUₚₗₐₛₜ of greater than 5 GPa to the surface of the carrier body;
c) optionally applying an intermediate layer to the protective layer;
d) applying a running layer to the protective layer or to the optional intermediate layer; and
e) optionally applying lubricating varnish to the running layer.

32. The sliding element as claimed in claim 1, wherein the multiple layer comprises an intermediate layer arranged between the protective layer and the running layer, wherein the intermediate layer contains a metal (Me); the intermediate layer comprises a comprises a first partial intermediate layer adjacent to the protective layer and a second partial intermediate layer adjacent to the running layer and also optionally a third partial intermediate layer arranged between the first and second partial intermediate layers; the first partial intermediate layer comprises a transition layer, which is optionally graduated with the protective layer, and subsequently a non-graduated layer which consists of Me-DLC or of Si-DLC; the second partial intermediate layer consists of Me and is optionally designed so as to be graduated with the first partial intermediate layer; the optional third partial intermediate layer consists of metal carbide (MeCₓ) or SiCₓ and is optionally designed so as to be graduated with the first and/or second partial intermediate layer; and the intermediate layer has an overall thickness of 0.2 to 5 μm.

33. The sliding element as claimed in claim 1, wherein the multiple layer comprises a bonding layer arranged between the protective layer and the carrier body or between the protective layer and the base layer, wherein the bonding layer comprises a first partial bonding layer adjacent to the carrier body or to the base layer and a second partial bonding layer which is adjacent to the protective layer and is optionally designed so as to be graduated with the first partial bonding layer; the first partial bonding layer consists of Ti or Cr and the second partial bonding layer consists of titanium nitride (TiNₓ) or chromium nitride (CrNₓ); and the bonding layer has an overall thickness of 0.2 to 5 μm.

34. The sliding element as claimed in one or more of claim 33, wherein the protective layer comprises a first partial protective layer adjacent to the bonding layer, to the base layer or to the carrier body and a second partial protective layer which is adjacent to the first partial protective layer and is optionally designed so as to be graduated with the first partial protective layer and also possibly a third partial protective layer which is arranged between the second partial protective layer and the running layer or the intermediate layer and is optionally designed so as to be graduated with the second partial protective layer; the first partial protective layer consists of a metal carbide MeCₓ with Me selected from the group consisting of Ti, V, Cr, Zr, Nb, Mo, Hf, Ta, W and Re; the second partial protective layer consists of Si-DLC or Me-DLC; the optional third partial protective layer consists of DLC; and the protective layer has an overall thickness of 0.5 to 10 μm.

35. The sliding element as claimed in claim 2, wherein the protective layer has a hardness HUₚₗₐₛₜ of greater than 20 GPa.

36. The sliding element as claimed in claim 2, wherein the protective laye has a hardness HUₚₗₐₛₜ of greater than 40 GPa.

37. The sliding element as claimed in claim 3, wherein the running layer has a hardness of 60 to 200 HV.

38. The sliding element as claimed in claim 3, wherein the running layer has a hardness of 80 to 140 HV.

39. The sliding element as claimed in claim 4, wherein the protective layer contains DLC having a hardness of greater than 30 GPa.

40. The sliding element as claimed in claim 6, wherein the protective layer has a thickness of 0.5 to 8 μm.

41. The sliding element as claimed in claim 6, wherein the protective layer has a thickness of 1 to 5 μm.

42. The sliding element as claimed in claim 8, wherein the maximum difference in height measured perpendicularly to the surface(s), peak-to-valley value in accordance with DIN 4768 Part 1, is less than 100 μm.

43. The sliding element as claimed in claim 8, wherein the maximum difference in height measured perpendicularly to the surface(s), peak-to-valley value in accordance with DIN 4768 Part 1, is less than 20 μm.

44. The sliding element as claimed in claim 9, wherein the inner surface(s) comprise a multiplicity of depressions having a maximum lateral dimension of 5 to 100 nm and a maximum depth of 1 to 200 μm.

45. The sliding element as claimed in claim 9, wherein the inner surface(s) comprise a multiplicity of depressions having a maximum lateral dimension of 10 to 20 μm; and a maximum depth of 1 to 20 μm.

46. The sliding element as claimed in claim 10, wherein the inner surface(s) comprise a multiplicity of grooves having
a maximum width of 5 to 200 μm; and
a maximum depth of 1 to 100 μm.

47. The sliding element as claimed in claim 10, wherein the inner surface(s) comprise a multiplicity of grooves having
a maximum width of 10 to 20 μm; and
a maximum depth of 1 to 20 μm.

48. The sliding element as claimed in claim 12, wherein the bonding layer contains Ti, TiN_{X}, Cr, CrN_{y}, Ni, NiCr or a Cr/NiCr alloy and has a thickness of 0.5 to 3 μm.

49. The sliding element as claimed in claim 13, wherein the base layer consists of bronze, brass or an aluminum alloy and has a thickness of 100 to 800 μm.

50. The sliding element as claimed in claim 13, wherein the base layer has a thickness of 200 to 500 μm.

51. The sliding element as claimed in claim 15, wherein the bonding layer contains Ti, TiNₓ, Cr, CrN_{y}, Ni, NiCr or a Cr/NiCr alloy and has a thickness of 0.2 to 5 μm.

52. The sliding element as claimed in claim 15, wherein the bonding layer has a thickness of 0.5 to 3 μm.

53. The sliding element as claimed in claim 16, wherein the carrier body consists of steel.

54. The sliding element as claimed in claim 18, wherein the intermediate layer contains Cr, Ni, NiCr or a Cr/NiCr alloy and has a thickness of 0.5 to 3 μm.

55. A process for producing a sliding element as claimed in claim 31, wherein the protective layer is preferably deposited by means of PVD and/or PCVD.

56. The sliding element as claimed in claim 32, wherein the intermediate layer contains a a carbide-forming metal selected from the group consisting of Ti, V, Cr, Zr, Nb, Mo, Hf, Ta, W and Re and the intermediate layer has an overall thickness of 0.3 to 0.6 μm.

57. The sliding element as claimed in claim 33, wherein the bonding layer has an overall thickness of 0.3 to 0.6 μm.

58. The sliding element as claimed in claim 1, wherein the protective layer has an overall thickness of 1 to 4 μm.
